(19) United States
(12) Patent Application Publication
(10) Pub. No.: US 2025/0063950 A1
(43) Pub. Date: Feb. 20, 2025

(54) PROCESSING METHOD OF BONDED WAFER

(71) Applicant: DISCO CORPORATION, Tokyo (JP)

(72) Inventor: Tomoka MORI, Tokyo (JP)

(21) Appl. No.: 18/782,393

(22) Filed: Jul. 24, 2024

(30) Foreign Application Priority Data
Aug. 16, 2023 (JP) 2023-132472

(51) Int. Cl. H10N 30/086; B24B 7/22

(52) U.S. Cl. CPC H10N 30/086; B24B 7/228

(57) ABSTRACT

Disclosed is a processing method of a bonded wafer, the bonded wafer including a first wafer having a chamfered portion formed on an outer periphery thereof and a second wafer bonded with the first wafer, by grinding and thinning the first wafer. The processing method includes the following steps: arranging a protective film on a side of the second wafer; holding the bonded wafer on a side of the protective film on a chuck table of a processing machine configured to remove the chamfered portion and removing the chamfered portion formed on the outer periphery of the first wafer; rinsing the bonded wafer from which the chamfered portion has been removed; peeling off the protective film from the second wafer; and holding the bonded wafer on the side of the second wafer on a chuck table of a grinding machine, and grinding the first wafer.

### BACKGROUND OF THE INVENTION

### Field of the Invention

The present invention relates to a processing method of a bonded wafer, the bonded wafer including a first wafer having a chamfered portion formed on an outer periphery thereof and a second wafer bonded with the first wafer, by grinding and thinning the first wafer.

### Description of the Related Art

A wafer, on a front surface of which a plurality of devices such as integrated circuits (ICs) or large-scale integrated (LSI) circuits is formed in isolation from one another by scribe lines, is ground at a back surface thereof to a desired thickness by a grinding machine, and is then divided into individual device chips by a cutting machine or the like. The divided device chips are used in electronic equipment such as mobile phones or personal computers.

Further, thin film surface acoustic wave (TF-SAW) devices, which are indispensable for communication equipment such as mobile phones and each excite a surface acoustic wave by comb-shaped electrodes of regular pattern formed on a thin film or substrate of a piezoelectric material, are fabricated by bonding a lithium tantalate (LiTaO₃=LT) wafer (hereinafter referred to as an “LT wafer”) or a lithium niobate (LiNbO₃=LN) wafer (hereinafter referred to as an “LN wafer”) as a piezoelectric body on a wafer of silicon, sapphire, quartz, or glass as a support substrate to form a bonded wafer, thinning the LT wafer or the LN wafer to a desired thickness (for example, 5 μm) with a grinding machine, and then forming the comb-shaped electrodes in a usable region around a center on a front surface of the LT wafer or the LN wafer. The resulting bonded wafer is then divided into individual TF-SAW device chips, which are ready for installation in various kinds of communication equipment.

Reflecting a move toward a multiband system that enables, for example, a single smartphone to be compatible with a plurality of bands, there is also a growing interest in devices formed from the above-described LT or LN material.

As a processing machine that grinds the above-described bonded wafer, there is known a grinding machine configured including a chuck table that is rotatable with a wafer held under suction thereon, a moving mechanism that moves the chuck table to a mounting/dismounting region where the wafer is mounted or dismounted and a grinding region where the wafer is ground, a loading mechanism that loads the wafer onto the chuck table in the mounting/dismounting region, an unloading mechanism that unloads the wafer from the chuck table after its grinding, and grinding means rotatably including a grinding wheel that grinds the wafer held on the chuck table moved to the grinding region while supplying grinding water to the wafer (see, for example, JP 2015-230971A).

### SUMMARY OF THE INVENTION

However, the above-described LT wafer or LN wafer is a material that has high cleavability and is very difficult to perform grinding processing. If an LT wafer or LN wafer of 350 μm thickness bonded on a silicon substrate or the like is ground to a thickness of 5 to 1 μm, for example, a problem arises in that a sharp, thin, and brittle region like a knife edge is formed on an outer periphery in the course of grinding processing, cracks occur and spread from the outer periphery to a usable region inside the LT wafer or the LN wafer, and the resulting device chips have low quality. Such a problem is not limited to a case in which a bonded wafer is formed with an LT wafer or an LN wafer, and the LT wafer or the LN wafer is ground to a thickness of 5 to 1 μm, but may also arise with a bonded wafer formed with another material having high cleavability.

The present invention therefore has as an object thereof the provision of a processing method of a bonded wafer, which can solve the problem that, if, for example, an LT wafer or LN wafer having high cleavability and bonded on a silicon substrate or the like is ground to a thickness of 5 to 1 μm by a grinding machine, a sharp, thin, and brittle region like a knife edge is formed on an outer periphery in the course of grinding processing, cracks occur and spread from the outer periphery to a usable region inside the LT wafer or the LN wafer, and the resulting device chips have low quality.

In accordance with an aspect of the present invention, there is provided a processing method of a bonded wafer, the bonded wafer including a first wafer having a chamfered portion formed on an outer periphery thereof and a second wafer bonded with the first wafer, by grinding and thinning the first wafer. The processing method includes a protective film arrangement step of arranging a protective film on a side of the second wafer, a chamfered-portion removing step of holding the bonded wafer on a side of the protective film on a chuck table of a processing machine configured to remove the chamfered portion and removing the chamfered portion formed on the outer periphery of the first wafer, a rinsing step of rinsing the bonded wafer from which the chamfered portion has been removed, a peeling step of peeling off the protective film from the second wafer, and a grinding step of holding the bonded wafer on the side of the second wafer on a chuck table of a grinding machine and grinding the first wafer.

Preferably, the first wafer may contain any one of lithium tantalate or lithium niobate, and the second wafer may contain any one of silicon, sapphire, quartz, or glass. Preferably, in the protective film arrangement step, the protective film may be a thermocompression bonding film.

According to the processing method of the present invention, no sharp region like a knife edge is formed on the outer periphery of the first wafer when the first wafer is ground and thinned, and no cracks occur and spread from the outer periphery to an inside of the first wafer in the course of the thinning of the first wafer. The above-mentioned low quality problem is therefore eliminated. Further, contaminants that include cutting debris generated in the chamfered-portion removing step do not stick to the side of the second wafer, owing to the arrangement of the protective film on the side of the second wafer in the protective film arrangement step before performing the chamfered-portion removing step. Furthermore, the protective film with contaminants stuck thereon is peeled off and removed by performing the peeling step. When the bonded wafer is held on the chuck table of the grinding machine upon performing the grinding step, contaminants are hence prevented from being held between the second wafer and the chuck table, thereby also making it possible to grind the first wafer to a uniform thickness when the first wafer is ground thin.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting how a bonded wafer as a workpiece is formed;

FIG. 2 is a perspective view depicting how a protective film is laid on the bonded wafer depicted in FIG. 1;

FIG. 3A is a perspective view depicting how the protective film is thermocompression-bonded to the bonded wafer in a protective film arrangement step of a processing method for the bonded wafer, according to an embodiment of the present invention;

FIG. 3B is a fragmentary cross-sectional view depicting, on an enlarged scale, an outer periphery of the bonded wafer with the protective film bonded thereto;

FIG. 4A is a perspective view depicting how the bonded wafer is placed on the chuck table;

FIG. 4B is a perspective view depicting how a chamfered portion of a first wafer of the bonded wafer is removed in a chamfered-portion removing step of the processing method according to the embodiment;

FIG. 5 is a perspective view depicting how a rinsing step of the processing method according to the embodiment is performed;

FIG. 6 is a perspective view depicting how a peeling step of the processing method according to the embodiment is performed;

FIG. 7 is an overall perspective view of a grinding machine that performs a grinding step of the processing method according to the embodiment;

FIG. 8A is a perspective view depicting how coarse grinding processing is performed in the grinding step; and

FIG. 8B is a perspective view depicting how finish grinding processing is performed in the grinding step.

### DETAILED DESCRIPTION OF THE PREFERRED EMBODIMENT

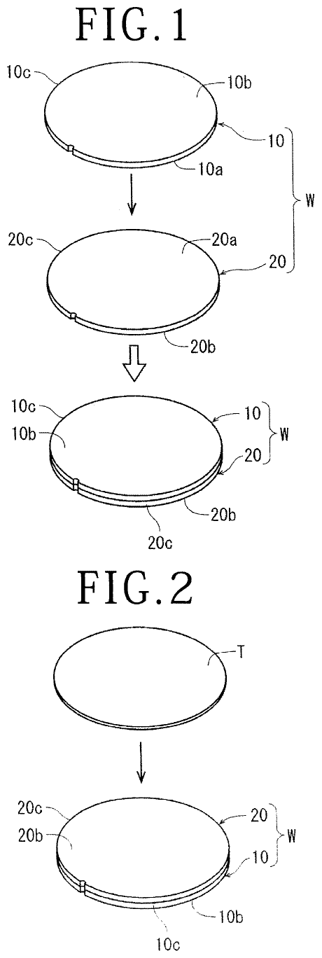

With reference to the attached drawings, a description will hereinafter be made in detail about a processing method for a bonded wafer, according to an embodiment of the present invention. FIG. 1 depicts, by way of example, how a bonded wafer W to be processed by the processing method of this embodiment is formed. As depicted in the figure, the bonded wafer W is formed of a first wafer 10, which is to be ground by the below-described processing method, and a second wafer 20, which is bonded to the first wafer 10 and supports the first wafer 10. The bonded wafer W has a diameter of, for example, 200 mm, and the first wafer 10 is, for example, an LT wafer of 350 μm thickness. Meanwhile, the second wafer 20 is a silicon wafer to be bonded as a support substrate that supports the first wafer 10, and has the same dimensions as the first wafer 10. The bonded wafer W is formed into an integrated structure by bonding a front surface 10a of the first wafer 10 and a front surface 20a of the second wafer 20 together, for example, using a known room temperature joining method. The first wafer 10 has been subjected, at an outer periphery thereof, to chamfering processing, so that a chamfered portion 10c is formed on the outer periphery. The second wafer 20 has also been subjected, at an outer periphery thereof, to chamfering processing, so that a chamfered portion 20c is formed on the outer periphery.

After the first wafer 10 has been thinned to a desired thickness by grinding the first wafer 10 at a back surface 10b thereof with use of the below-described processing method of this embodiment, electrodes are formed in individual regions defined by scribe lines (depiction omitted) on the front surface 10a of the first wafer 10, and the resulting bonded wafer W is then divided along the scribe lines, whereby TF-SAW device chips are formed (details omitted). It is to be noted that the first wafer 10, which is bonded to the second wafer 20 to form the bonded wafer W, is not limited to the above-described LT wafer, and an LN wafer may also be adopted. It is also to be noted that the second wafer 20, which supports the first wafer 10, is not limited to the above-described silicon wafer, and may also be a wafer of, for example, one of sapphire, quartz, or glass.

The processing method of this embodiment, which is to be performed on the above-described bonded wafer W, includes grinding and thinning the back surface 10b of the first wafer 10 in the bonded wafer W that includes the first wafer 10 having the chamfered portion 10c formed on the outer periphery thereof and the second wafer 20 bonded with the first wafer 10, and is performed through the following procedures.

### (Protective Film Arrangement Step)

After the above-described bonded wafer W is provided upon performance of the processing method of this embodiment, a protective film T is laid on a side of a back surface 20b of the second wafer 20 in a protective film arrangement step as depicted in FIG. 2. The protective film T to be used in this protective film arrangement step is preferably selected from thermocompression bonding films, which are formed with dimensions equal to or slightly greater than the second wafer 20, include no glue or the like having self-adhesiveness and arranged on bonding surfaces, and are suited for thermocompression bonding. A material suited for thermocompression bonding is a material that is softened to exhibit self-adhesiveness when heated to a particular temperature, and is selected, for example, from polyolefin films. It is to be noted that, in the embodiment to be described hereinafter, a polyethylene (PE) film as a specific polyolefin film is selected as the protective film T. It is however to be noted that, as the protective film T in the present invention, films other than the above-described thermocompression bonding films are not excluded, and a self-adhesive film with a glue arranged on a surface thereof may also be used. Even in this case, the base material of the self-adhesive film is preferably resin that softens when heated.

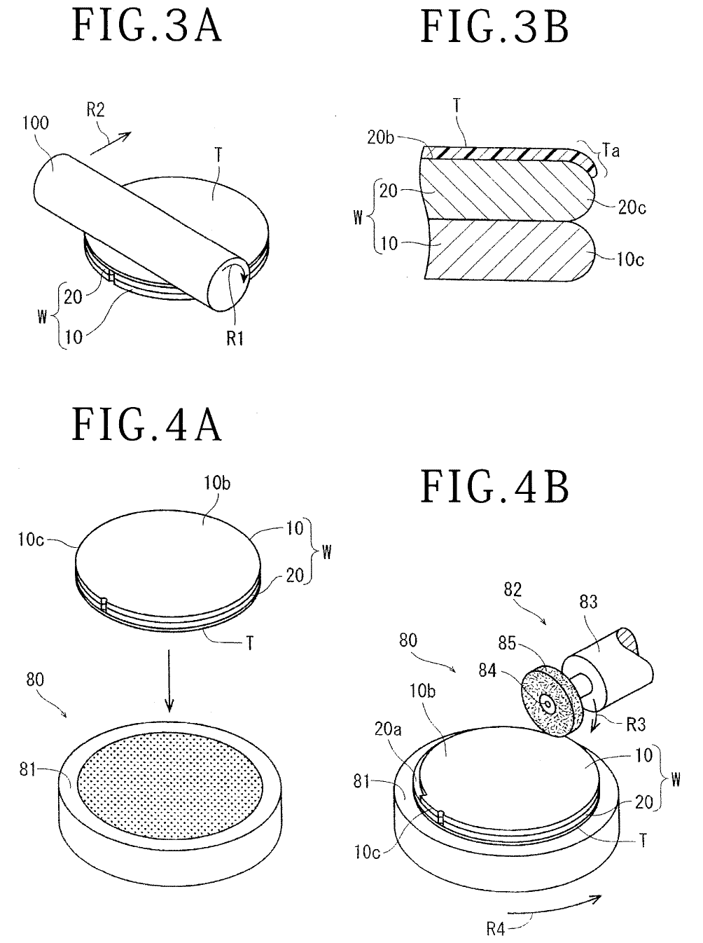

After the protective film T has been laid on the back surface 20b of the second wafer 20 of the bonded wafer W as described above, a thermocompression bonding roller 100 is positioned above the protective film T as depicted in FIG. 3A. The thermocompression bonding roller 100 internally includes a heater (depiction omitted) and a temperature sensor (depiction omitted), and is coated on a surface thereof with a fluorinated resin to prevent entrapment of the protective film T. The protective film T is thermocompression-bonded to the back surface 20b of the second wafer 20 by heating the surface of the thermocompression bonding roller 100 to a predetermined temperature at which the protective film T is softened to exhibit self-adhesiveness (for example, 100° C.), and with the thermocompression bonding roller 100 pressed against the protective film T from above, rolling the thermocompression bonding roller 100 in a direction indicated by an arrow R1 and at the same time, moving the thermocompression bonding roller 100 in a direction indicated by an arrow R2. As a result of the protective film T being heated, softened, and compression-bonded to the back surface 20b of the second wafer 20, the protective film T is now bonded such that, as depicted in FIG. 3B, the protective film T is in close contact with the back surface 20b of the second wafer 20 and also wraps around the outer periphery of the second wafer 20, on which the chamfered portion 20c is formed, as indicated by Ta in the figure. The protective film arrangement step is now completed. It is to be noted that the mode to perform the thermocompression bonding of the protective film T in the protective film arrangement step is not limited to the above-described mode. For example, a heated flat plate may be pressed against the protective film T from above to perform thermocompression bonding of the protective film T to the back surface 20b of the second wafer 20, or hot air may be blown from above to heat the protective film T and to perform thermocompression bonding of the protective film T to the back surface 20b of the second wafer 20 by wind pressure.

If the above-described protective film T is selected from polyolefin-based films, a selection can be made of any one of a polypropylene (PP) film or a polystyrene (PS) film instead of the above-described PE film. Upon thermocompression bonding, the heating temperature however needs an appropriate adjustment to a softening temperature corresponding to the selected film.

### (Chamfered-Portion Removing Step)

The bonded wafer W, with the protective film T bonded to the back surface 20b of the second wafer 20, is next transferred to a processing machine, for example, a cutting machine 80 depicted (only in parts) in FIGS. 4A and 4B, to remove the chamfered portion 10c of the first wafer 10. The cutting machine 80 includes at least a chuck table 81 depicted in FIG. 4A, and a cutting it 82 depicted in FIG. 4B. The chuck table 81 has a holding surface constituted by a member having air permeability, and is connected to suction means (depiction omitted), so that a negative pressure is produced in an upper surface. The cutting unit 82 includes a disk-shaped cutting blade 85, which is fitted to a distal end of a spindle 84 rotatably held by a spindle housing 83. After the bonded wafer W has been transferred to the cutting machine 80 as described above, the bonded wafer W is placed on the chuck table 81 with the side, where the protective film T is arranged, directed downward and the side of the back surface 10b of the first wafer 10 directed upward as depicted in FIG. 4A, and the above-described suction means is operated to hold the bonded wafer W under suction. The cutting blade 85 of the cutting unit 82 is next rotated at a predetermined speed in a direction indicated by an arrow R3, and is positioned on the outer periphery of the first wafer 10, on which the chamfered portion 10c is formed. While cutting-in feed is performed at a depth corresponding to the thickness of the first wafer 10, the chuck table 81 is then rotated in a direction indicated by an arrow R4 As a consequence, the outer periphery, which includes the chamfered portion 10c, of the first wafer 10 is completely removed over the entirety thereof, and an outer peripheral portion of the front surface 20a of the second wafer 20 is exposed, whereby the chamfered-portion removing step is completed. It is to be noted that the cutting blade 85 preferably has a thickness (for example, 3 mm) corresponding to or greater than a width of the chamfered portion 10c to be removed. However, the cutting blade 85 is not necessarily required to have a thickness corresponding to or greater than the width of the chamfered portion 10c, and may have a thickness of a dimension smaller than the width of the chamfered portion 10c. If this is the case, the outer periphery of the first wafer 10 may be cut in a plurality of steps such that the outer periphery of the first wafer 10 is removed over the width corresponding to the chamfered portion 10c.

The chamfered-portion removing step is however not limited to the above-described mode. The chamfered portion 10c may also be removed by forming an annular cut groove, which extends from the first wafer 10 to the second wafer 20, in a boundary portion (not depicted) between a usable region, where electrodes are to be formed, around a center and the chamfered portion 10c in the first wafer 10, and then applying an external force to the chamfered portion 10c.

### (Rinsing Step)

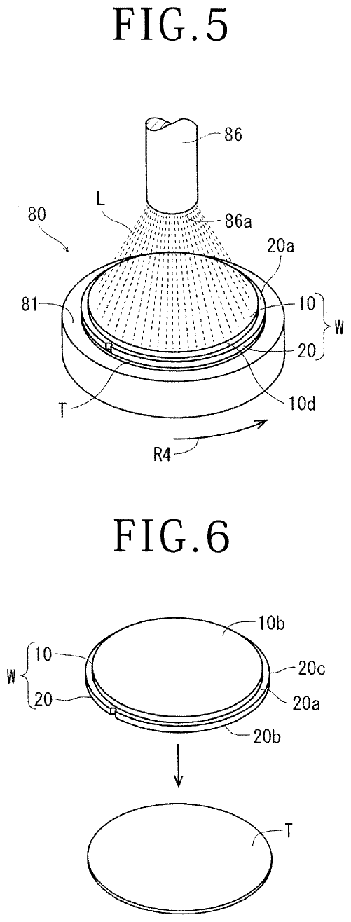

After the chamfered port-ion 10c of the first wafer 10 has been removed as described above, a moving mechanism (depiction omitted) that moves the chuck table 81 is operated to position the bonded wafer W right below a rinsing unit 86 as depicted in FIG. 5. Next, the chuck table 81 is rotated in a direction indicated by the arrow R4, and at the same time, rinse water (for example, pure water L) is ejected from rinse water ejection apertures 86a of the rinsing unit 86 to rinse the bonded wafer W from which the chamfered portion 10c has been removed as described above. It is to be noted that, after the pure water L is ejected for a predetermined period of time from the rinsing unit 86, air may be ejected to perform a drying step for removing water from the bonded wafer W.

### (Peeling Step)

After the rinsing step has been performed as described above, a peeling step is performed to peel off the protective film T arranged on the back surface 20b of the second wafer 20 as depicted in FIG. 6. It is to be noted that, when the protective film T is peeled off, cooling or heating may be preferred according to the characteristics of the protective film T to facilitate the peeling-off of the protective film T.

### (Grinding Step)

After the peeling step has been performed as described above, a grinding step is performed to grind the side of the first wafer 10. It is to be noted that, in the grinding step to be described hereinafter, the description will be made on the basis of an example in which the grinding is performed by separating it into coarse grinding processing to grind the thickness of the first wafer 10 from 350 μm to 20 μm, and finish grinding processing to grind the first wafer 10, the thickness of which has been reduced to 20 μm, until its thickness is reduced to 5 μm.

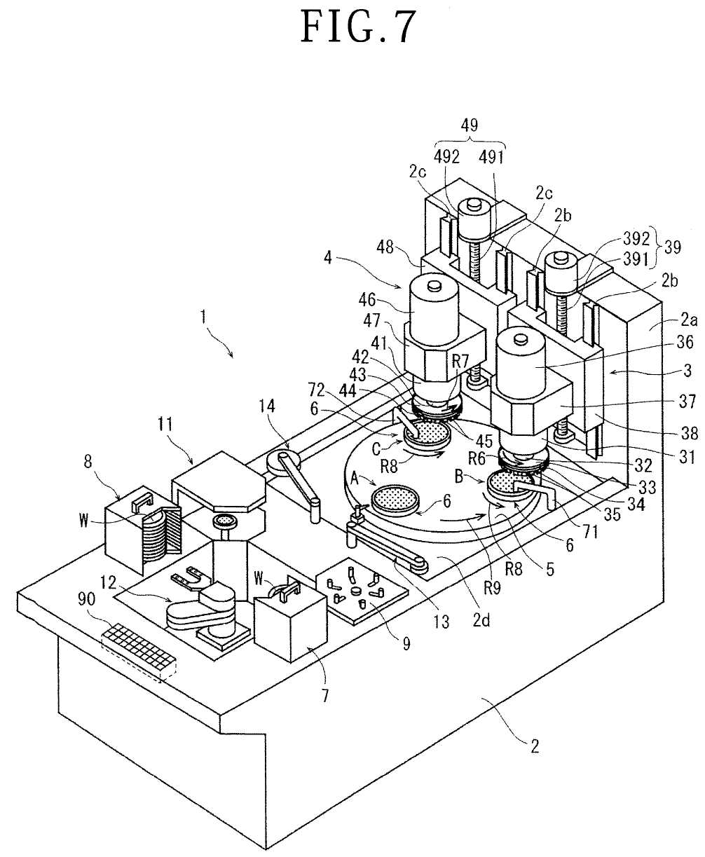

In FIG. 7, a grinding machine 1 suited for the processing method of this embodiment is depicted. As depicted in FIG. 7, the grinding machine 1 includes a machine housing 2 of a substantially parallelepiped shape, and on a side of a rearward end of the machine housing 2, a support wall 2a is disposed upright. On a forward surface of this support wall 2a, two pairs of guide rails 2b and 2c are disposed extending in an up-down direction. On one pair of guide rails, specifically the guide rails 2b, first grinding means 3 is fitted movably in the up-down direction as means for performing coarse grinding processing, and on the other one of guide rails, specifically the guide rails 2c, second grinding means 4 is fitted movably in the up-down direction as means for performing finish grinding processing.

The first grinding means 3 includes a unit housing 31, a wheel mount 33 arranged on a lower end of a spindle 32 rotatably supported on the unit housing 31, a grinding wheel 34 secured to the wheel mount 33 and carrying on a lower surface thereof a plurality of grinding stones 35 for coarse grinding arranged in an annular pattern, an electric motor 36 mounted on an upper end of the unit housing 31 to rotate the wheel mount 33 in a direction indicated by an arrow R6, and a moving base 38 supporting the unit housing 31 via a support member 37.

On the moving base 38, guide slots are disposed in sliding engagement with the above-described guide rails 2b, so that the first grinding means 3 is supported movably in the up-down direction. The depicted grinding machine 1 includes a grinding feed mechanism 39, which raises and lowers the moving base 38 of the first grinding means 3 along the guide rails 2b such that the first grinding means 3 is brought away from and close to the above-described bonded wafer W held on one of chuck tables 6 to be described subsequently herein, specifically the chuck table 6 positioned in the below-mentioned first grinding region B. The grinding feed mechanism 39 includes an externally threaded rod 391 arranged in the up-down direction in parallel with the guide rails 2b and rotatably supported on the support wall 2a, a pulse motor 392 for rotationally driving the externally threaded rod 391, and an internally threaded block (not depicted) secured to the moving base 38 and maintained in threaded engagement with the externally threaded rod 391. By normally and reversely driving the externally threaded rod 391 with the pulse motor 392, the first grinding means 3 is moved in the up-down direction.

The second grinding means 4 that performs finish grinding is configured substantially the same as the above-described first grinding means 3, and includes a unit housing 41, a wheel mount 43 arranged on a lower end of a spindle 42 rotatably supported on the unit housing 41, a grinding wheel 44 secured to the wheel mount 43 and carrying on a lower surface thereof a plurality of grinding stones 45 for finish grinding arranged in an annular pattern, an electric motor 46 mounted on an upper end of the unit housing 41 to rotate the wheel mount 43 in a direction indicated by an arrow R7, and a moving base 48 supporting the unit housing 41 via a support member 47.

On the moving base 48, guide slots are disposed in sliding engagement with the guide rails 2c disposed on the above-described support wall 2a, so that the second grinding means 4 is supported movably in the up-down direction. The depicted grinding machine 1 also includes a grinding feed mechanism 49, which raises and lowers the moving base 48 of the second grinding means 4 along the guide rails 2c such that the second grinding means 4 is brought away from and close to the above-described bonded wafer W held on the chuck table 6 positioned in the below-mentioned second grinding region C. The grinding feed mechanism 49 includes an externally threaded rod 491 arranged in the up-down direction in parallel with the guide rails 2c and rotatably supported on the support wall 2a, pulse motor 492 for rotationally driving the externally threaded rod 491, and an internally threaded block (not depicted) secured to the moving base 48 and maintained in threaded engagement with the externally threaded rod 491. By normally and reversely driving the externally threaded rod 491 with the pulse motor 492, the second grinding means 4 is moved in the up-down direction.

The grinding machine 1 includes a turn table 5 arranged on a forward side of the above-described support wall 2a such that the turn table 5 lies substantially in flush with the upper surface of the machine housing 2. This turn table 5 is formed in a disk shape of relatively large diameter, and is appropriately rotated by a rotary drive mechanism (not depicted in FIG. 7) in a drainage pan 2d disposed in the upper surface of the machine housing 2 to recover grinding water that contains grinding debris. On the turn table 5, the above-mentioned three chuck tables 6 are arranged at angular intervals of 120 degrees as holding means for holding bonded wafers W, respectively. Each chuck table 6 is configured rotatably in a direction indicated by an arrow R8. Each chuck table 6 has a holding surface (upper surface) formed in a disk shape by a member having air permeability, and is connected to suction means (depiction omitted).

By rotation of the turn table 5 in a direction indicated by an arrow R9, the three chuck tables 6 arranged on the turn table 5 are each sequentially moved in an order of a loading/unloading region A where the bonded wafer W is loaded onto and unloaded from the chuck table 6, the first grinding region B where coarse grinding processing is performed by the first grinding means 3, the second grinding region C where finish grinding processing is performed by the second grinding means 4, the loading/unloading region A. The turn table 5 therefore functions as positioning means that positions each chuck table 6 in the loading/unloading region A, the first grinding region B, and the second grinding region C. In addition, optical non-contact thickness gauges 71 and 72 are also arranged at positions adjacent the first grinding region B and the second grinding region C, respectively, in the above-described drainage pan 2d to detect the thicknesses (heights) of the bonded wafers W held on the chuck tables 6 positioned in the first grinding region B and the second grinding region C, respectively.

The grinding machine 1 includes a first cassette 7, a second cassette 8, position matching means 9, a rinsing unit 11, workpiece unloading/loading means 12, transfer means 13, and an unloading mechanism 14. The first cassette 7 accommodates a plurality of bonded wafers W obtained after the above-described chamfered-portion removing step, in which the chamfered portion 10c of each first wafer 10 has been removed, but before grinding processing. The second cassette 8 is arranged on an opposite side of the first cassette 7 with respect to the loading/unloading region A, and accommodates the plurality of bonded wafers W obtained after grinding processing. The position matching means 9 is arranged between the first cassette 7 and the loading/unloading region A, and allows temporary placement of each bonded wafer W thereon with their centers matched with each other. The rinsing unit 11 is arranged between the loading/unloading region A and the second cassette 8. The workpiece unloading/loading means 12 unloads each bonded wafer W from the first cassette 7 to the position matching means 9, and loads each rinsed bonded wafer W from the rinsing unit 11 into the second cassette 8. The transfer means 13 transfers each bonded wafer W which has been subjected to position matching on the position matching means 9, onto the chuck table 6 positioned in the unloading/loading region A. The unloading mechanism 14 unloads each bonded wafer W which is held on the chuck table 6 positioned in the unloading/loading region A after grinding of its first wafer 10 by the second grinding means 4, and transfers the bonded wafer W to the rinsing unit 11.

On a near side of the machine housing 2, on which the workpiece unloading/loading means 12 is arranged, a controller 90 including a control panel for instructing grinding processing and specifying processing conditions is arranged. The controller 90 includes a central processing unit (CPU) that performs processing in accordance with a control program, a read-only memory (ROM) that stores the control program and the like, a read/write random-access memory (RAM) as storage means for storing operation results and the like, and an input interface and an output interface (which are both omitted in FIG. 7). By the controller 90 configured as described above, the above-described individual operating parts of the grinding machine 1 are controlled, and information and the like on the processing are appropriately displayed on display means (depiction omitted).

The grinding machine 1 has configurations as generally described above, and the grinding processing in this embodiment is performed as described hereinafter.

The above-described bonded wafer W is transferred onto the chuck table 6 positioned in the unloading/loading region A, and is placed and held there with the side of the second wafer 20 directed downward and the side of the first wafer 10 directed upward. When the bonded wafer W is held on the chuck table 6, the following steps are performed: an unloading step that unloads the bonded wafer W from the first cassette 7 by the workpiece unloading/loading means 12; a position matching step that places the bonded wafer W which has been unloaded by the workpiece unloading/loading means 12, on the position matching means 9, and performs position-matching of the center of the bonded wafer W; and a holding step that operates the transfer means 13 to transfer the bonded wafer W from the position matching means 9 onto the chuck table 6 positioned in the unloading/loading region A, places the bonded wafer W on the chuck table 6 with the side of the second wafer 20 directed downward, and operates the suction means (depiction omitted) to hold the bonded wafer W on the chuck table 6 under suction.

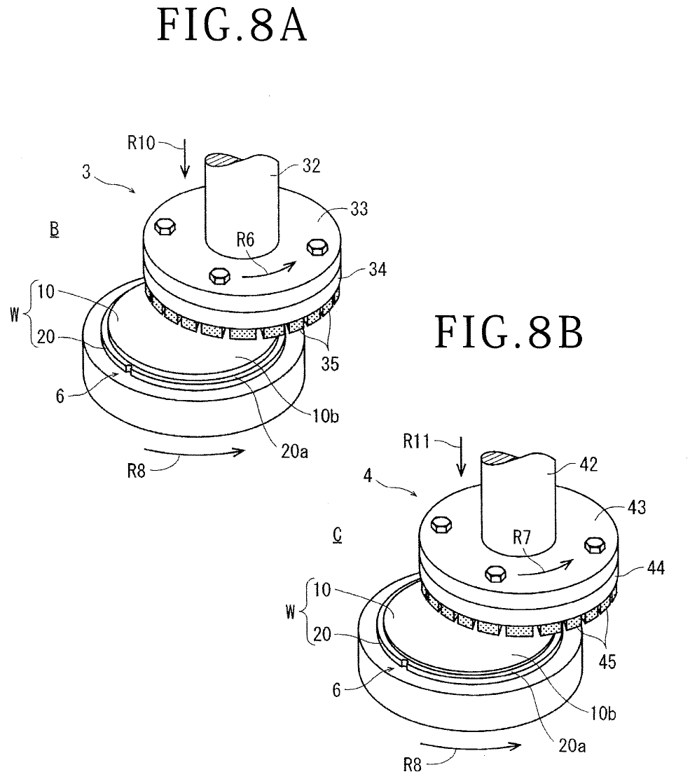

Next, the turn table 5 is rotated over 120° in the above-described direction indicated by the arrow R9, such that the chuck table 6 with the bonded wafer W held thereon is positioned in the first grinding region B depicted in FIG. 7. As depicted in FIG. 8A, the chuck table 6 is then rotated at a predetermined rotational speed (for example, 300 rpm) in the above-described direction indicated by the arrow R8 to rotate the bonded wafer W held on the chuck table 6, and at the same time, the grinding wheel 34 of the first grinding means 3 is rotated at a predetermined rotational speed (for example, 6,000 rpm) in the direction indicated by the arrow R6. The grinding feed mechanism 39 is then operated to lower the first grinding means 3 in a direction indicated by an arrow R10, and while grinding water is supplied to a grinding point at which the bonded wafer W and the grinding stones 35 come into contact with each other by grinding water supplying means (depiction omitted), the grinding stones 35 are brought into contact with the back surface 10b of the first wafer 10. After that, the bonded wafer W is fed for grinding at a predetermined grinding feed rate (for example, 1.0 μm/second) by the grinding feed mechanism. 39, so that the first wafer 10 is subjected to coarse grinding processing by the grinding stones 35. This coarse grinding processing can be performed while the thickness of the bonded wafer W is detected by the above-described non-contact thickness gauge 71 (depiction omitted in FIG. 8A), and the coarse grinding processing is performed until the thickness (350 μm) of the first wafer 10 before the coarse grinding processing is reduced to 20 μm.

After completion of the above-described coarse grinding processing, the turn table 5 is rotated over 120° in the above-described direction indicated by the arrow R9, so that the bonded wafer W, the coarse grinding processing of which has been completed, is moved from the first grinding region B to the second grinding region C. Here, another bonded wafer W before coarse grinding processing has been transferred and held on the chuck table 6 to be moved from the unloading/loading region A to the first grinding region B, and the bonded wafer W before coarse grinding processing is to be positioned in the first grinding region B. As depicted in FIG. 8B, after the positioning of the bonded wafer W in the second grinding region C, the chuck table 6 is then rotated at a predetermined rotational speed (for example, 300 rpm) in the above-described direction indicated by the arrow R8 to rotate the bonded wafer W held on the chuck table 6, and at the same time, the above-described grinding spindle 42 of the second grinding means 4 is rotated at a predetermined rotational speed (for example, 6,000 rpm) in the direction indicated by the arrow R7.

The above-described grinding feed mechanism 49 is then operated to lower the second grinding means 4 in a direction indicated by an arrow R11 such that the grinding stones 45 are brought into contact with the back surface 10b of the first wafer 10, and while grinding water is supplied to a grinding point by grinding water supplying means (depiction omitted), the bonded wafer W is fed for grinding at a predetermined grinding feed rate (for example, 1.0 μm/second) by the grinding feed mechanism 49, so that the back surface 10b of the first wafer 10 is subjected to finish grinding processing by the grinding stones 45. It is to be noted that, upon performing this finish grinding processing, the finish grinding processing can be performed while the thickness of the bonded wafer W is detected by the above-described non-contact thickness gauge 72, and the finish grinding processing is performed until the thickness (20 μm) of the first wafer 10 before the performance of the finish grinding processing is reduced, for example, to 5 μm. It is also to be noted that, while finish grinding processing is performed in the second grinding region C, coarse grinding processing is performed in the first grinding region B while being allowed to proceed in unison, and onto the chuck table 6 positioned in the unloading/loading region A, a further bonded wafer W before coarse grinding processing is transferred and placed from the first cassette 7, and is held there under suction.

After the finish grinding processing has been applied and the first wafer 10 has been ground to the desired thickness in the second grinding region C as described above, the grinding step for the bonded wafer W in this embodiment is completed, and the processing method of this embodiment is ended. After that, the turn table 5 is rotated to move the chuck table 6 again to the unloading/loading region A, the bonded wafer W is unloaded by the unloading mechanism 14, and after rinsing and drying in the rinsing unit 11, the workpiece unloading/loading means 12 is operated to accommodate the rinsed bonded wafer W in the second cassette 8.

According to the processing method of the above-described embodiment, the chamfered-portion removing step that removes the chamfered portion 10c formed on the outer periphery of the first wafer 10 is performed before performing the grinding step that grinds the first wafer 10. When the back surface 10b of the first wafer 10 is ground and thinned, no sharp region like a knife edge is therefore formed on the outer periphery of the first wafer 10, and no cracks hence occur and spread from the outer periphery to the inner usable region of the first wafer 10 in the course of the thinning of the first wafer 10 to 5 μm or smaller. The above-mentioned low quality problem is therefore eliminated.

Further, the protective film T is arranged on the side of the second wafer 20 in the protective film arrangement step before performing the chamfered-portion removing step as described above. Contaminants that include cutting debris generated the chamfered-portion removing step are therefore prevented from sticking to the side of the second wafer 20. Furthermore, the peeling step is performed after performing the above-described rinsing step. This makes it possible to remove, along with the protective film T, contaminants that have made their way into a portion between the chuck table 81 and the protective film T in the chamfered-portion removing step, so that the side of the second wafer 20 can be held in a clean state free of stuck contaminants on the chuck table 6 of the grinding machine 1. As a result, even when the first wafer 10 is ground extremely thin, for example, to 5 to 1 μm, the first wafer 10 can be ground with high precision to a uniform thickness without allowing the bonded wafer W to partly come off upward from the chuck table 6 under influence of contaminants.

Moreover, the selection of the protective film T, which is to be used in the above-described protective film arrangement step, from thermocompression-bonding films makes it possible to bond the protective film T such that the outer periphery of the second wafer 20 is wrapped around, thereby ensuring to prevent contaminants from making their way into a portion between the second wafer 20 and the protective film T in the chambered-portion removing step.

The above and other objects, features and advantages of the present invention and the manner of realizing them will become more apparent, and the invention itself will best be understood from a study of the following description and appended claims with reference to the attached drawings showing a preferred embodiment of the invention.

What is claimed is:

1. A processing method of a bonded wafer, the bonded wafer including a first wafer having a chamfered portion formed on an outer periphery thereof and a second wafer bonded with the first wafer, by grinding and thinning the first wafer, the processing method comprising:
a protective film arrangement step of arranging a protective film on a side of the second wafer;
a chamfered-portion removing step of holding the bonded wafer on a side of the protective film on a chuck table of a processing machine configured to remove the chamfered portion and removing the chamfered portion formed on the outer periphery of the first wafer;
a rinsing step of rinsing the bonded wafer from which the chamfered portion has been removed;
a peeling step of peeling off the protective film from the second wafer; and
a grinding step of holding the bonded wafer on the side of the second wafer on a chuck table of a grinding machine and grinding the first wafer.

2. The processing method according to claim 1, wherein the first wafer contains any one of lithium tantalate or lithium niobate, and the second wafer contains any one of silicon, sapphire, quartz, or glass.

3. The processing method according to claim 1, wherein, in the protective film arrangement step, the protective film is a thermocompression bonding film.
